(19) United States
(12) Patent Application Publication
(10) Pub. No.: US 2026/0362035 A1
(43) Pub. Date: Nov. 12, 2026

(54) METHODS OF OPERATION OF RANDOM PATTERN GENERATOR, PHASE-LOCKED LOOP, AND IMAGE SENSOR INCLUDING THE SAME

(71) Applicant: SAMSUNG ELECTRONICS CO., LTD., Suwon-si (KR)

(72) Inventors: Seungmin SUH, Suwon-si (KR); Heejin JANG, Suwon-si (KR); Boram HER, Suwon-si (KR)

(73) Assignee: SAMSUNG ELECTRONICS CO., LTD., Suwon-si (KR)

(21) Appl. No.: 19/394,321

(22) Filed: Nov. 19, 2025

(30) Foreign Application Priority Data
May 12, 2025 (KR) 10-2025-0061435

(51) Int. Cl. H04N 25/76; H03K 19/20; H03L 7/089; H03L 7/099; H04N 25/617; H04N 25/709

(52) U.S. Cl. CPC H04N 25/7795; H03L 7/0891; H03L 7/099; H04N 25/617; H04N 25/709; H03K 19/20

(57) ABSTRACT

An image sensor includes a phase-locked loop generating an output clock signal, and receiving the output clock signal as feedback to perform a phase-locked operation for the output clock signal, a random pattern generator generating output data of a Pseudo Random Binary Sequence (PRBS) pattern based on the output clock signal, and a power management unit (PMU)receiving the output data and operating.

### CROSS-REFERENCE TO RELATED APPLICATION(S)

This application is based on and claims benefit of priority to Korean Patent Application No. 10-2025-0061435, filed on May 12, 2025 in the Korean Intellectual Property Office, the inventive concept of which is incorporated herein by reference in its entirety.

### BACKGROUND

The disclosure relates to an operating method of a random pattern generator, a phase-locked loop, and an image sensor including the same.

A phase-locked loop (PLL) circuit included in an image sensor may receive a reference clock signal from an external source and convert the signal into a high-speed clock signal required for internal operation. Also, the PLL circuit may supply a clock signal for operating a power management unit. In the image sensor, current changes due to high-speed switching of a power management unit and a plurality of harmonic components included in a switching frequency are concentrated in a specific frequency band, so that electromagnetic interference (EMI) may be generated, thereby deteriorating the performance of the image sensor.

In a related art system, to suppress electromagnetic interference generated in the power management unit, a phase-locked loop dedicated to the power management unit may be added. However, when the phase-locked loop dedicated to the power management unit is added to an image sensor, an area occupied by the phase-locked loop in the image sensor may increase, and power consumed by the phase-locked loop may increase. Therefore, although electromagnetic interference generated in the image sensor may decrease, there may be a problem of increasing power consumption and the area of the image sensor.

### SUMMARY

According to an aspect of the inventive concept, there is provided an apparatus and a method for generating output data of a Pseudo Random Binary Sequence (PRBS) pattern based on an output clock signal generated in a phase-locked loop and supplying the output data to a power management unit, thereby reducing power consumed by an image sensor and an area of the image sensor, and improving the deterioration in performance of the image sensor due to electromagnetic interference.

According to an aspect of the disclosure, there is provided an image sensor, including: a phase-locked loop (PLL) circuit configured to generate an output clock signal, and receive a feedback signal corresponding to the output clock signal to perform a phase-locked operation for the output clock signal; a random pattern generator circuit configured to generate output data of a Pseudo Random Binary Sequence (PRBS) pattern based on the output clock signal; and a power management unit (PMU) circuit configured to receive the output data and operate based on the output data.

According to another aspect of the disclosure, there is provided an operating method of a random pattern generator circuit, including: receiving an output clock signal in a phase-locked loop; outputting a first output signal and a first phase modified signal having a phase difference of 90 degrees from the first output signal, at a first point in time based on the output clock signal; outputting a second output signal and a second phase modified signal having a phase difference of 90 degrees from the second output signal, at a second point in time after the first point in time based on the output clock signal; selecting one output signal among the first output signal and the second output signal; selecting one phase modified signal among the first phase modified signal and the second phase modified signal; generating output data of a Pseudo Random Binary Sequence (PRBS) pattern based on the selected output signal and the selected phase modified signal; and supplying the output data to a power management unit (PMU) circuit.

According to another aspect of the disclosure, there is provided a phase-locked loop, including: a voltage controlled oscillator circuit configured to generate an output clock signal; a divider circuit configured to receive the output clock signal, and divide the output clock signal into a feedback clock signal having a constant phase difference; a phase frequency detector circuit configured to a difference in phase and frequency between a reference clock signal and the feedback clock signal, and adjust a control voltage input to the voltage controlled oscillator circuit to reduce the difference; and a random pattern generator circuit configured to receive the output clock signal, generate output data of a Pseudo Random Binary Sequence (PRBS) pattern based on the output clock signal, and input the output data to a power management unit (PMU) circuit.

### BRIEF DESCRIPTION OF DRAWINGS

The above and other aspects, features, and advantages of the disclosure will be more clearly understood from the following detailed description, taken in conjunction with the accompanying drawings:

FIG. 1 is a diagram schematically illustrating an image sensor according to an example embodiment of the present inventive concept;

FIG. 2 is a diagram schematically illustrating a pixel circuit of an image sensor according to an example embodiment of the present inventive concept;

FIGS. 3 to 5 are diagrams schematically illustrating an image sensor including a random pattern generator according to an example embodiment of the present inventive concept;

FIGS. 6 and 7 are circuit diagrams schematically illustrating charge pumps included in a power management unit according to an example embodiment of the present inventive concept;

FIGS. 8 and 9 are block diagrams schematically illustrating a phase-locked loop according to an example embodiment of the present inventive concept;

FIGS. 10 and 11 are diagrams schematically illustrating a random pattern generator according to an example embodiment of the present inventive concept;

FIGS. 12 and 13 are diagrams provided to describe an operation of a random pattern generator according to an example embodiment of the present inventive concept;

FIGS. 14A to 14D and 15A to 15D are diagrams provided to describe an operation of an image sensor according to an example embodiment of the present inventive concept; and

FIG. 16 is a flowchart provided to describe an operation of an image sensor according to an example embodiment of the present inventive concept.

### DETAILED DESCRIPTION

Below, embodiments of the disclosure will be described in detail and clearly to such an extent that an ordinary one in the art easily carries out the disclosure. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

To clearly describe the disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description, the disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

According to one or more embodiments, various operations and/or functions described below may be implemented in a hardware approach. For example, according to some embodiments, the methods described below may be implemented by an electronic device configured to carry out a described operation(s) or function(s). The electronic device may include blocks, which may be referred to herein as managers, units, modules, hardware components, “~er” terms or the like, may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure. However, the disclosure is not limited thereto, and as such, the blocks, which may be referred to herein as managers, units, modules, or the like, may be software modules implemented by software codes, program codes, software instructions, or the like. The software modules may be executed on one or more processors.

According to one or more embodiments, various methods, operations and/or functions described below may be implemented or supported by artificial intelligence technology or one or more computer programs, each of which is configured with computer-readable program code and executed on a computer-readable medium. The term “computer-readable medium” includes any type of medium that may be accessed by a computer, such as read-only memory (ROM), random-access memory (RAM), a hard disk drive, a compact disc (CD), a digital video disc (DVD), or other types of memory. A “non-transitory” computer-readable medium excludes wired, wireless, optical, or other communication links that transmit transitory electrical signals or other signals. The non-transitory computer-readable medium includes a medium in which data can be permanently stored, and a medium in which data can be stored and later overwritten, such as a rewritable optical disk or an erasable memory device.

Hereinafter, example embodiments of the present inventive concept will be described with reference to the attached drawings.

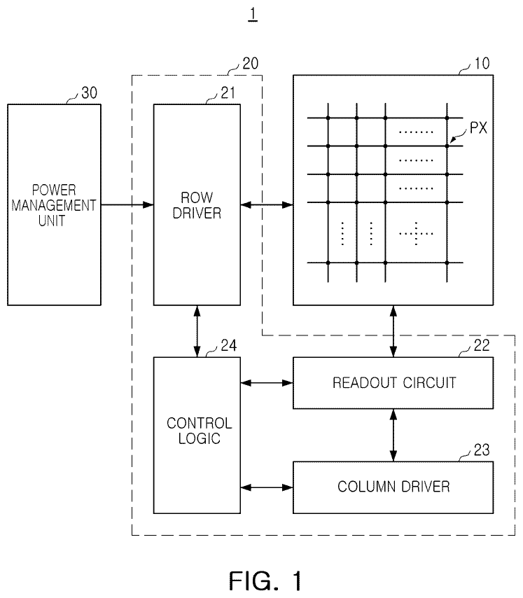

FIG. 1 is a block diagram schematically illustrating an image sensor according to an example embodiment of the present inventive concept.

Referring to FIG. 1, an image sensor 1 may include a pixel array 10, a peripheral circuit 20, and a power management unit 30. However, the disclosure is not limited thereto, and as such, according to an embodiment, the image sensor 1 may include one or more other components.

The pixel array 10 may include a plurality of pixels PX provided in an array form along a plurality of rows and a plurality of columns. Each of the plurality of pixels PX may include at least one photoelectric conversion element configured to generate charges in response to light, and a pixel circuit configured to generate a pixel signal corresponding to the charges generated by the photoelectric conversion element. The photoelectric conversion element may include a photodiode formed of a semiconductor material, and/or an organic photodiode formed of an organic material.

For example, the pixel circuit may include a floating diffusion, a transfer transistor, a reset transistor, a driving transistor, a selection transistor, and the like. The configuration of the pixels PX may vary depending on the example embodiments. For example, each of the pixels PX may include an organic photodiode including an organic material, or may be implemented as a digital pixel. In an example case in which the pixels PX are implemented as digital pixels, each of the pixels PX may include an analog-to-digital converter for outputting a digital pixel signal.

The peripheral circuit 20 may include circuits for controlling the pixel array 10. For example, the peripheral circuit 20 may include a row driver 21, a readout circuit 22, a column driver 23, a control logic 24, and the like. The row driver 21 may drive the pixel array 10 in units of row lines. For example, the row driver 21 may generate a transmission control signal controlling a transmission transistor of the pixel circuit, a reset control signal controlling a reset transistor, a selection control signal controlling a selection transistor, and the like, and input the same to the pixel array 10 in units of row lines.

The readout circuit 22 may include a correlated double sampler CDS, an analog-to-digital converter ADC, and the like. The correlated double samplers may be connected to the pixels PX through column lines. The correlated double samplers may read pixel signals from pixels PX connected to a row line selected by a row line select signal of a row driver 21 through column lines. The analog-to-digital converter may convert a pixel signal detected by a correlated dual sampler into a digital pixel signal and transmit the same to a column driver 23.

The column driver 23 may include a latch that can temporarily store the digital pixel signal or buffer circuit and an amplifier circuit that may process the digital pixel signal received from the readout circuit 22. The row driver 21, the readout circuit 22, and the column driver 23 may be controlled by the control logic 24. The control logic 24 may include a timing controller for controlling an operation timing of the row driver 21, the readout circuit 22, and the column driver 23.

The power management unit 30 may be a power control circuit configured to supply voltage to various circuits inside the image sensor. The power management unit 30 may generate analog power supplied to the pixel array 10, digital power supplied to the peripheral circuit 20, a voltage supplied to the I/O interface, or the like, based on a reference voltage input through an external power source or an internal voltage generator.

For example, the power management unit 30 may generate a voltage provided to the row driver 21. The power management unit 30 may provide the voltage required for the row driver 21 to generate a transmission control signal, a reset control signal, a selection control signal, and the like. However, the present inventive concept is not limited thereto.

A power management unit 30 according to an embodiment of the present disclosure may be implemented in a charge pump configuration. For example, the power management unit 30 may include at least one pumping capacitor, and may generate a voltage based on the pumping capacitor. The power management unit 30 may receive a voltage from the outside, boost, lower, and invert the input voltage, and output the voltage. The power management unit 30 may include, in addition to the pumping capacitor, a Low Dropout Regulator (LDO), a power switch, and a control circuit for power-on sequencing.

In an example embodiment of the present inventive concept, to improve the performance of the image sensor 1 to be deteriorated by electromagnetic interference (EMI) generated in the power management unit 30, the power management unit 30 may receive output data through a random pattern generator. The random pattern generator may generate output data of a Pseudo Random Binary Sequence (PRBS) pattern based on an output clock signal of a phase-locked loop. The output data may contain a wider spectrum of frequency components the output clock signal based on a single frequency. Therefore, power may be distributed over a broader frequency range compared to the output clock signal based on a single frequency, and energy may be prevented from being concentrated on a specific frequency component, thereby reducing electromagnetic interference generated in the power management unit 30.

In addition, since a separate phase-locked loop of the clock signal supplied to the power management unit 30, the power consumption of the image sensor and the area of the image sensor may be reduced. In an example embodiment of the present inventive concept, an image sensor 1 having improved PPA (Power, Performance, Area) may be provided, by including a power management unit 30 receiving output data from a random pattern generator.

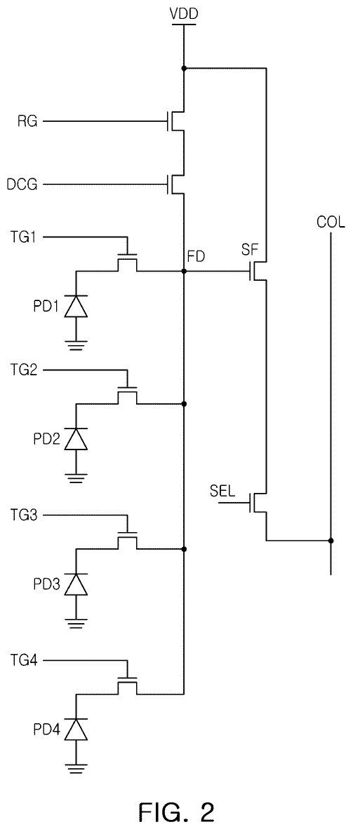

FIG. 2 is a diagram schematically illustrating a pixel circuit of an image sensor according to an example embodiment of the present inventive concept.

Referring to FIG. 2, a first photodiode PD1, a second photodiode PD2, a third photodiode PD3, and a fourth photodiode PD4 of a pixel circuit may be connected to each other, and may output a reset voltage and a pixel voltage to a column line COL. For example, the pixel circuit may include a first transfer transistor TG1, a second transfer transistor TG2, a third transfer transistor TG3, a fourth transfer transistor TG4, a reset transistor RG, a source follower transistor SF, a selection transistor SEL, a dual conversion gain transistor DCG, and the like. For example, the source follower transistor SF may be referred to as a driving transistor. The pixel circuit may be connected to a peripheral circuit of the image sensor through the column line COL, and the peripheral circuit may obtain a reset voltage and a pixel voltage through the column line COL to generate a pixel signal. An example embodiment illustrated in FIG. 2 illustrates a structure in which first to fourth photodiodes PD1 to PD4 share one floating diffusion region FD. However, the present inventive concept is not limited thereto, and it may also be implemented in a non-shared structure in which each photodiode includes an independent floating diffusion region FD.

In an example case in which the first photodiode PD1, the second photodiode PD2, the third photodiode PD3, and the fourth photodiode PD4 are exposed to light and generate charges during an exposure time, the first transfer transistor TG1, the second transfer transistor TG2, the third transfer transistor TG3, and the fourth transfer transistor TG4 may be sequentially turned on. The peripheral circuit may obtain a first pixel signal after the first transfer transistor TG1 is turned on, obtain a second pixel signal after the second transfer transistor TG2 is turned on, obtain a third pixel signal after the third transfer transistor TG3 is turned on, and obtain a fourth pixel signal after the fourth transfer transistor TG4 is turned on.

Referring to FIGS. 1 and 2, the power management unit 30 illustrated in FIG. 1 may provide a voltage required to generate a transmission control signal for controlling the transmission transistors TG1, TG2, TG3, and TG4 of the pixel circuit, a reset control signal for controlling the reset transistor RG, and a selection control signal for controlling the selection transistor SG. In addition, the power management unit 30 may generate a power voltage VDD required for the operation of the pixel circuit and supply the same to the pixel array.

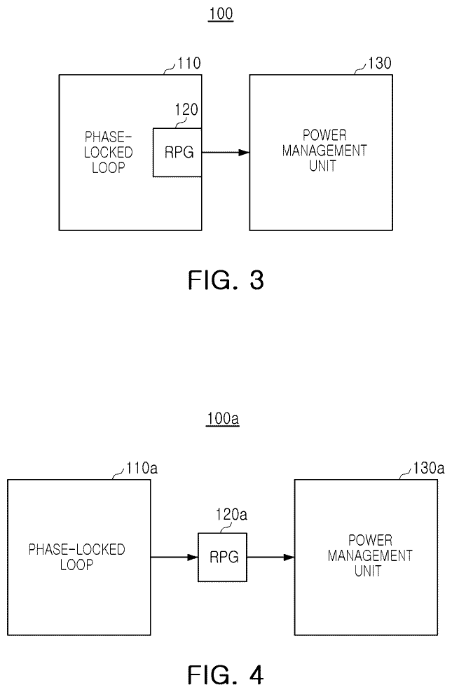

FIGS. 3 to 5 are diagrams schematically illustrating an image sensor including a random pattern generator according to an example embodiment of the present inventive concept.

In an example embodiment of the present inventive concept, an image sensor 100 may include a phase-locked loop 110 and a power management unit 130. For example, the phase-locked loop 110 may be referred to as a phase-locked loop circuit and the power management unit 130 as a power management unit circuit. A clock signal generated by the phase-locked loop 110 may be supplied to the power management unit 130.

The phase-locked loop 110 may generate an output clock signal, and may receive the output clock signal as feedback to perform a phase-locked operation for the output clock signal. For example, the phase-locked loop 110 may generate an output clock signal, and may receive a feedback signal corresponding to the output clock signal to perform a phase-locked operation for the output clock signal. In an example embodiment, the phase-locked loop 110 may be a system phase-locked loop that receives a reference clock signal from the outside, generates a high-frequency output clock signal, and supplies the high-frequency output clock signal to a pixel array of an image sensor, an analog-to-digital converter, an image signal processor, and the like. For example, the system phase-locked loop may receive the reference clock signal from a source outside the phase-locked loop 110.

In another example embodiment, the phase-locked loop 110 may generate a high-frequency output clock signal for transmitting data over a high-speed interface. The output clock signal may be used for high-speed serial interfaces such as, for example, Mobile Industry Processor Interface Camera Serial Interface/Display Serial Interface (MIPI CSI/DSI), Low-Voltage Differential Signaling (LVDS), Universal Serial Bus (USB), Peripheral Component Interconnect Express (PCIe), High-Definition Multimedia Interface (HDMI), and the like.

According to an embodiment, the image sensor 100 may include random pattern generator 120. The random pattern generator 120 may be referred to as a random pattern generator circuit. For example, the random pattern generator 120 may receive the output clock signal from the phase-locked loop 110, and generate output data of a PRBS pattern based on the supplied output clock signal. The output data of the PRBS pattern may be generated by a Linear Feedback Shift Register (LFSR) circuit, and the random pattern generator 120 may generate the output data based on a rising edge or a falling edge of the output clock signal. For example, the random pattern generator 120 may generate the output data at a rising edge of the output clock signal or at a falling edge of the output clock signal. The random pattern generator 120 may supply generated output data to the power management unit 130.

The output data of the PRBS pattern is data generated based on a frequency of the output clock signal. The output data of the PRBS pattern may include various frequency components compared to the output clock signal. According to an embodiment, the output data of the PRBS pattern may have a wider spectrum of frequency components than the output clock signal based on a single frequency, and may have the effect of the output power being spread and distributed in a frequency domain compared to the output clock signal based on a single frequency. Therefore, by supplying output data to the power management unit 130, it is possible to prevent energy from being concentrated on a specific frequency component, thereby reducing electromagnetic interference generated in the power management unit 130.

In addition, since a separate phase-locked loop is not required to widen a frequency band of the clock signal supplied to the power management unit 130, the power consumption of the image sensor 100 and an area of the image sensor 100 may be reduced. Therefore, the image sensor 100 according to an example embodiment of the present inventive concept may improve the performance of the image sensor by including the random pattern generator 120 generating output data of a PRBS pattern.

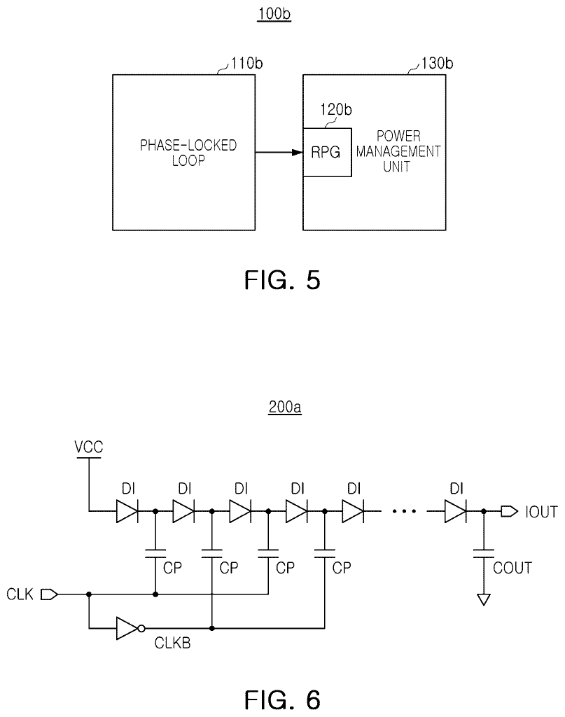

In an example embodiment illustrated in FIG. 3, the pattern generator 120 may be included in a phase-locked loop 110 as illustrated in FIG. 3. In an example embodiment illustrated in FIG. 4, the random pattern generator 120a may be provided separately from a phase-locked loop 110a and a power management unit 130a. For example, the random pattern generator 120a may be provided between the phase-locked loop 110a and the power management unit 130a. In an example embodiment illustrated in FIG. 5, the random pattern generator 120b may be included in a power management unit 130.

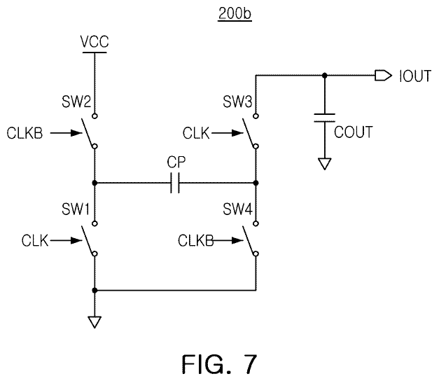

FIGS. 6 and 7 are circuit diagrams schematically illustrating charge pumps included in a power management unit according to an example embodiment of the present inventive concept.

According to an example embodiment of the present inventive concept, the power management unit may include a charge pump the receives a voltage from an external source and provide an output current IOUT to generate a power supply voltage of a higher level than the input voltage. For example, the charge pump may include switches which are turned on or off by a clock signal, and at least one pumping capacitor. An amount of charge supplied by the charge pump may vary depending on the frequency of the clock signal. The clock signal may be output data generated by a random pattern generator based on an output clock signal output from a phase-locked loop. The clock signal may be a predetermined signal.

According to an embodiment, a power management unit may include a charge pump 200a as illustrated in FIG. 6. For example, the charge pump 200a included in the power management unit may include a plurality of diodes DI, a plurality of pumping capacitors CP, and an output capacitor COUT. The plurality of diodes DI may be connected to each other in series, and the plurality of pumping capacitors CP may be connected to nodes between the plurality of diodes DI. The first diode may receive a power supply voltage VCC having a certain level, and the last diode may output an output current IOUT to the output node.

Each of the plurality of pumping capacitors CP may be charged or discharged by a clock signal CLK or a complementary clock signal CLKB which is phase-shifted to have an opposite phase to the clock signal CLK by an inverter INV. For example, in an example embodiment illustrated in FIG. 6, odd-numbered pumping capacitors CP may be charged or discharged by a clock signal CLK, and even-numbered pumping capacitors CP may be charged or discharged by a complementary clock signal CLKB.

According to an embodiment illustrated FIG. 7, a charge pump 200b may include a plurality of switch elements SW1, SW2, SW3 and SW4 and at least one pumping capacitor CP and an output capacitor COUT. For example, the charge pump 200b may be included in a power management unit. According to an embodiment, among the plurality of switch elements SW1 to SW4, the second switch element SW2 may receive a power voltage VCC, and the first switch element SW1 and the fourth switch element SW4 may be connected to a node to which a ground voltage, or the like, is supplied. The third switching element SW3 may be connected between the output node and the pumping capacitor CP.

The first switch element SW1 and the third switch element SW3 may be turned on or off by a clock signal CLK, and the second switch element SW2 and the fourth switch element SW4 may be turned on/off by a complementary clock signal CLKB. In an example case in which the second switching element SW2 and the fourth switching element SW4 are turned on, the pumping capacitor CP may be charged by the power supply voltage VCC. In an example case in which the first switching element SW1 and the third switching element SW3 are turned on, the charge charged in the pumping capacitor CP may be shared with the output capacitor COUT, and an output current IOUT may be output through the output node. The output current IOUT output from the power management unit may supply a voltage for driving the pixel array and peripheral circuits, and the like.

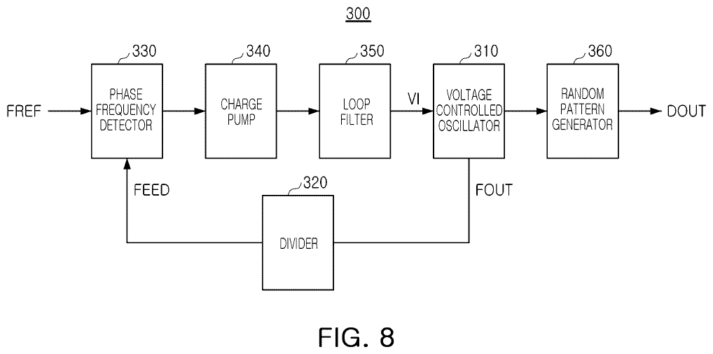

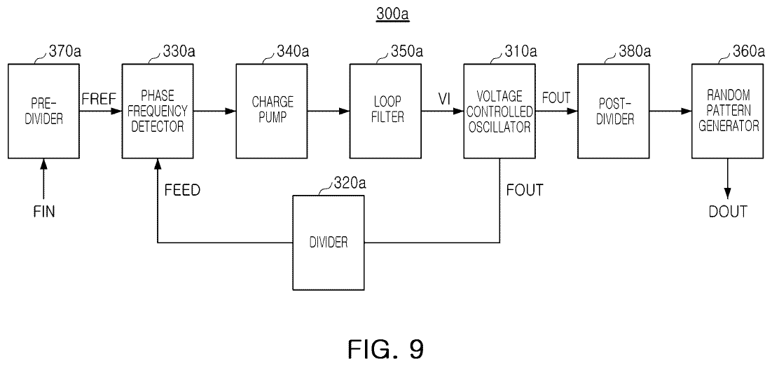

FIGS. 8 and 9 are block diagrams schematically illustrating a phase-locked loop according to an example embodiment of the present inventive concept.

Referring to FIG. 8, a phase-locked loop 300 may include a voltage controlled oscillator 310, a divider 320, and a phase frequency detector 330. However, the disclosure is not limited thereto, and as such, according to an embodiment, the phase-locked loop 300 may include one or more other components. For example, the phase-locked loop 300 may further include a charge pump 340, a loop filter 350, and a random pattern generator 360.

According to an embodiment, the voltage controlled oscillator VCO 310 may control an output frequency FOUT based on an input control voltage VI. The voltage controlled oscillator 310 may control the output frequency FOUT in response to a control voltage VI supplied through a phase frequency detector PFD 330 and a loop filter 350, and the output frequency FOUT may be fed back to the phase frequency detector 330 through a divider 320, thereby forming a closed loop structure. According to an embodiment, the divider 320 may divide the output frequency FOUT based on a division ratio to generate a feedback clock signal FEED. For example, the divider 320 may divide the output frequency FOUT according to a preset division ratio to generate a feedback clock signal FEED, and the feedback clock signal FEED may be supplied to a phase frequency detector 330.

According to an embodiment, the phase frequency detector 330 may detect a difference in phase and frequency between a reference clock signal FREF and the feedback clock signal FEED, and may output an UP or DOWN signal based on the difference in phase and frequency. For example, the phase frequency detector 330 may detect a difference in phase and/or frequency between a reference clock signal FREF and the feedback clock signal FEED, and may output an UP or DOWN signal according to the difference in phase and/or frequency. The up or down signal may be a control signal generated by the phase frequency detector 330, and may be used to synchronize the reference clock signal FREF. The up signal may be generated based on the feedback clock signal FEED being slower than the reference clock signal FREF, and the down signal may be generated based on the feedback clock signal FEED being faster than the reference clock signal FREF. For example, the up signal may be generated when the feedback clock signal FEED is slower than the reference clock signal FREF, and the down signal may be generated when the feedback clock signal FEED is faster than the reference clock signal FREF. In other words, if the feedback clock signal FEED is slower than the reference clock signal FREF, the phase frequency detector 330 may generate the up signal to accelerate the feedback clock signal FEED, and if the feedback clock signal FEED is faster than the reference clock signal FREF, the phase frequency detector 330 may generate the down signal to decelerate the feedback clock signal FEED.

According to an embodiment, the phase frequency detector 330 may transmit the up or down signal to a charge pump 340, and the charge pump 340 may output charges in a source or sink manner based on the up or down signal. In an example case in which the up signal is input to the charge pump 340, a current source inside the charge pump 340 may be turned on, and current may be supplied to the loop filter 350, so that a level of the control voltage VI may increase. Therefore, the output frequency FOUT of the voltage controlled oscillator 310 may increase. On the other hand, in an example case in which the down signal is input to the charge pump 340, the current source inside the charge pump 340 may be turned on, and the current may be absorbed from the loop filter 350, so that a level of the control voltage VI may decrease. Therefore, the output frequency FOUT of the voltage controlled oscillator 310 may decrease.

In an example embodiment of the present inventive concept, the phase-locked loop 300 may further include the random pattern generator 360. However, the disclosure is not limited thereto, and as such, in an example embodiment, the random pattern generator 360 may not be included in the phase-locked loop 300, and may be provided separately from the phase-locked loop 300. The random pattern generator 360 may generate output data DOUT of a PRBS pattern using the output frequency FOUT of the voltage controlled oscillator 310.

The random pattern generator 360 may be implemented based on a linear feedback shift register (LFSR) structure, and output data DOUT is a bit string in which 0 and 1 are randomly mixed, and the output data DOUT may have a predetermined pattern length. For example, the pattern length may be determined according to the number of shift registers included in the random pattern generator 360. The output data DOUT generated by the random pattern generator 360 may be generated to include various frequency components.

The random pattern generator 360 may generate output data DOUT of the PRBS pattern based on an output frequency FOUT, thereby implementing a spread spectrum. The output data DOUT may spread the output frequency FOUT generated in a single frequency band to a wide frequency band. For example, the output data DOUT having a wider frequency band than the output frequency FOUT may distribute output power to the relatively wide frequency band compared to the output frequency FOUT. Therefore, the power management unit receiving the output data DOUT generated by the random pattern generator 360 and operating may reduce electromagnetic interference generated in the power management unit since energy is not concentrated in a specific frequency band, and the performance of the image sensor may be improved.

The phase-locked loop 300a according to the example embodiment illustrated in FIG. 9 may share the same or corresponding technical features as the phase-locked loop 300 examined in FIG. 8. For example, the phase-locked loop 300a may include a voltage controlled oscillator 310a, a divider 320a, a phase frequency detector 330a, a charge pump 340a, a loop filter 350a, and a random pattern generator 360a. Therefore, descriptions overlapping the configuration described in FIG. 8 will be brief or omitted.

In an example embodiment illustrated in FIG. 9, the phase-locked loop 300a may include a pre-divider 370a that receives an external clock FIN and dividing the external clock FIN by a predetermined multiple to generate a reference clock signal FREF. For example, a frequency of the external clock FIN may be about 6 to 24 MHz.

The phase-locked loop 300a may include a post-divider 380a that divides an output frequency FOUT by a predetermined multiple and inputting the same to the random pattern generator 360a. For example, the predetermined multiple may be ½. The random pattern generator 360a may generate output data DOUT of a PRBS pattern based on a divided clock of the output frequency FOUT, and an average frequency of the output data DOUT may be set to, for example, half the frequency of the output frequency FOUT. The output data DOUT of the PRBS pattern includes various frequency components, so the data is output over a wide frequency band, and may have the effect of the output power being spread and distributed in the frequency domain compared to the output frequency FOUT based on a single frequency. Therefore, when the output data DOUT is input to the power management unit, the electromagnetic interference generated in the power management unit may be reduced, and the performance of the image sensor may be improved.

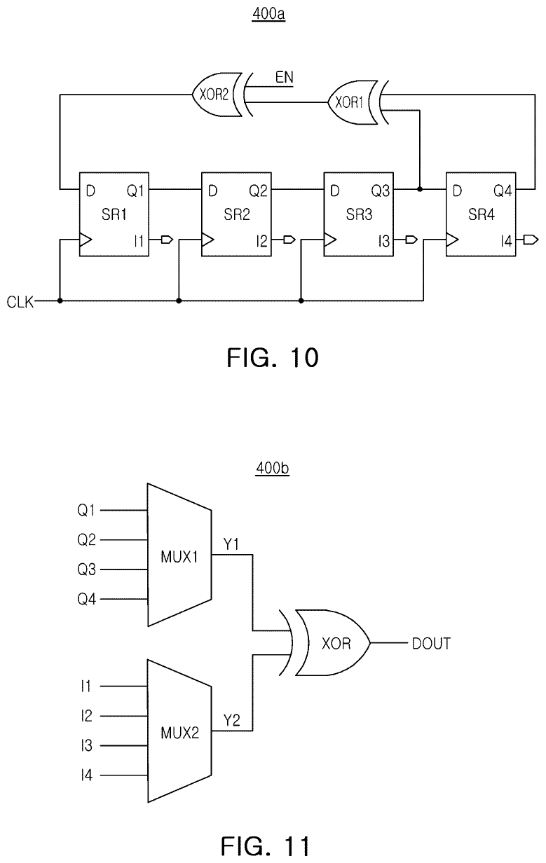

FIGS. 10 and 11 are diagrams schematically illustrating a random pattern generator according to an example embodiment of the present inventive concept.

Referring to FIG. 10, a random pattern generator 400a according to an example embodiment of the present inventive concept may include a plurality of shift registers SR1, SR2, SR3, and SR4. For example, the number of shift registers SR1 to SR4 may be two or more. In an example embodiment illustrated in FIG. 10, it is illustrated that the plurality of shift registers are provided in the number of four, but an example embodiment thereof is not limited thereto, and the number of shift registers may be seven or fourteen. Each of the plurality of shift registers SR1 to SR4 may include an input terminal, a clock terminal, and two output terminals. The plurality of shift registers SR1 to SR4 may operate synchronously according to the same clock signal CLK, and may shift output signals based on a rising edge of the clock signal CLK.

The plurality of shift registers SR1 to SR4 may be configured as a linear feedback structure connected to each other in series, and may generate output data of a PRBS pattern having a longer period than a input signal of the shift register SR1. The output data generated based on the plurality of shift registers SR1 to SR4 may have a wider spectrum band and may reduce electromagnetic interference by preventing energy from being concentrated on specific frequency components.

The random pattern generator 400a according to an example embodiment of the present inventive concept may include a plurality of shift registers SR1 to SR4 and one or more XOR gates. The XOR gates may generate output data of a PRBS pattern by utilizing specific output signals of the shift register for a feedback operation. For example, the one or more XOR gates may include a first XOR gates XOR1 and a second XOR gate XOR2. An XOR operation may be determined by a PRBS polynomial structure, which may determine complexity and a pattern length of the output data.

In an example embodiment illustrated in FIG. 10, the random pattern generator 400a may include a first shift register SR1, a second shift register SR2, a third shift register SR3, and a fourth shift register SR4. The first to fourth shift registers SR1 to SR4 may operate synchronously according to the same clock signal CLK, and may shift output signals based on the rising edge of the clock signal CLK.

The first shift register SR1 may output a first output signal Q1 and a first phase delay signal I1 having a phase difference of 90 degrees from the first output signal Q1. In an example embodiment, the first phase delay signal I1 may be a signal of which a phase thereof is 90 degrees ahead of the first output signal Q1, or a signal of which a phase thereof is 90 degrees delayed from the first output signal Q1. Similarly thereto, the second shift register SR2 may output a second output signal Q2 and a second phase delay signal I2 having a 90 degree phase difference from the second output signal Q2, the third shift register SR3 may output a third output signal Q3 and a third phase delay signal I3 having a phase difference of 90 degrees from the third output signal Q3, and the fourth shift register SR4 may output a fourth output signal Q4 and a fourth phase delay signal I4 having a phase difference of 90 degrees from the fourth output signal Q4. However, the disclosure is not limited thereto, and as such, the phase difference between the output signal and the phrase delay signal may be different than 90 degrees. Also, the phase delay signal may be referred to as a phase modified signal.

In an example embodiment illustrated in FIG. 10, the first XOR gate XOR1 may perform an XOR operation on a third output signal Q3 of a third shift register SR3 and a fourth output signal Q4 of a fourth shift register SR4 and input an operation result to an input terminal of the second XOR gate XOR2. The second XOR gate XOR2 may perform an XOR operation on the operation result of the first XOR gate XOR1 and an enable signal EN, and may feedback a final XOR operation result to an input terminal of the first shift register SR1. In other words, the plurality of shift registers SR1 to SR4 may be sequentially connected along a feedback path, and the final XOR operation result may be fed back to the input of the first shift register SR1 to form a loop.

The random pattern generator 400a according to an example embodiment of the present inventive concept may include the plurality of shift registers SR1 to SR4, and may generate output data having a PRBS pattern. By feeding back an output signal of a selected shift register through one or more XOR gates, the output data may be configured to have both randomness and periodicity, thereby forming a wide frequency spectrum including various frequency configurations. Accordingly, the output data generated by the random pattern generator 400a may be provided in a form in which fixed harmonic components are removed compared to a clock signal CLK, and by applying such output data to the power management unit, electromagnetic interference may be effectively suppressed.

Next, referring to FIG. 11, a random pattern generator 400b according to an example embodiment of the present inventive concept may include a first multiplexer MUX1, a second multiplexer MUX2, and an XOR gate XOR. According to an embodiment, the random pattern generator 400b may further include the components illustrates in FIG. 10. For example, the random pattern generator 400b may further include a plurality of shift registers SR1, SR2, SR3, and SR4 configured to output the first to fourth output signals Q1 to Q4, and the first to fourth phase delay signals I1 to I4.

The first multiplexer MUX1 may receive first to fourth output signals Q1 to Q4, output by each of the plurality of shift registers SR1, SR2, SR3, and SR4 (for example, as shown in FIG. 10). The first multiplexer MUX1 may select and output one output signal Y1 among the first to fourth output signals Q1 to Q4 by a first selection signal S1. For example, the first selection signal S1 may be composed of 2 bits, and may include a first bit S1[0] and a second bit S1[1]. The number of output signals input to the first multiplexer MUX1 is not limited to the embodiment illustrated in FIG. 11, and may be determined by the number of shift registers.

The second multiplexer MUX2 may receive first to fourth phase delay signals I1 to I4 output from each of the plurality of shift registers SR1, SR2, SR3, and SR4 (for example, as shown in FIG. 10). The second multiplexer MUX2 may select and output one phase delay signal Y2 among the first to fourth phase delay signals I1 to I4 by a second selection signal S2. For example, the second selection signal S2 also has a 2-bit structure, and may include a first bit S2[0] and a second bit S2[1]. The number of output signals input to the second multiplexer MUX2 is not limited to the embodiment illustrated in FIG. 11, and may be determined by the number of shift registers.

The XOR gate XOR may generate output data DOUT by performing an XOR operation on the output signal Y1 output from the first multiplexer MUX1 and the phase delay signal Y2 output from the second multiplexer MUX2. In other words, one output signal Y1 of the plurality of output signals Q1 to Q4 and one phase delay signal Y2 of the plurality of phase delay signals I1 to I4 may be combined through the XOR gate and provided as a single output.

Referring to FIG. 10, the random pattern generator 400a according to an example embodiment of the present inventive concept may include a plurality of shift registers SR1 to SR4. Output data DOUT of a PRBS pattern generated by the random pattern generator 400a includes various frequency components, and thus is output over a wide frequency band compared to an output signal based on a single frequency, and may have the effect of the output power being spread and distributed in the frequency domain.

However, in an example case in which output data DOUT is generated using only a plurality of shift registers SR1 to SR4, a pattern length of the output data DOUT may be limited by the number of shift registers and a polynomial structure. A frequency dispersion effect of the output data DOUT of the PRBS pattern generated accordingly may also have a limitation.

Referring to FIG. 11, the random pattern generator 400b according to an example embodiment of the present inventive concept may increase a pattern length and pattern diversity of output data DOUT by selectively combining output signals Q1 to Q4 having different phases and phase delay signals I1 to I4 through the first multiplexer MUX1, the second multiplexer MUX2, and the XOR gate XOR. As the pattern length of the output data DOUT increases, a frequency spectrum may become flat and power concentrated in a specific frequency component may be distributed over a wide frequency band. Therefore, the power management unit receiving output data DOUT may effectively reduce electromagnetic interference.

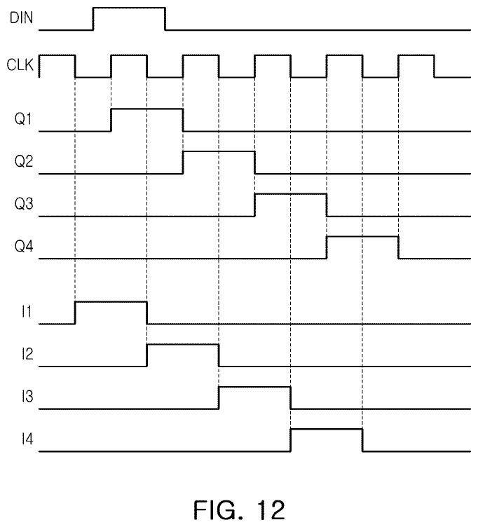

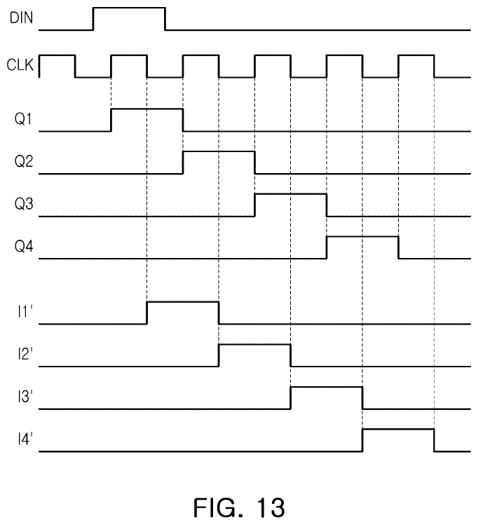

FIGS. 12 and 13 are diagrams provided to describe an operation of a random pattern generator according to an example embodiment of the present inventive concept.

FIG. 12 may be a graph illustrating output signals Q1 to Q4 and phase delay signals I1 to I4 of a plurality of shift registers SR1 to SR4 according to an example embodiment illustrated in FIG. 10.

Input data DIN may be input to an input terminal of the first shift register SR1 illustrated in FIG. 10. The input data DIN may be a final result value obtained by performing, by a second XOR gate XOR2, an XOR operation on an enable signal EN and output from a first XOR gate XOR1 performing an XOR operation on a third output signal Q3 and a fourth output signal Q4. The plurality of shift registers SR1 to SR4 may operate synchronously according to the same clock signal CLK. The clock signal CLK may be a signal output from a phase-locked loop receiving an external clock and generating a final clock.

Referring to FIGS. 10 and 12, in an example case in which the input data DIN is logic high and the clock signal CLK is a rising edge, the first shift register SR1 illustrated in FIG. 10 may output a first output signal Q1 which is logic high for one period of the clock signal CLK. The first shift register SR1 may output a first phase delay signal I1 of which a phase thereof is 90 degrees ahead of the first output signal Q1.

As described in FIG. 10, the second shift register SR2 may output a second output signal Q2 and a second phase delay signal I2 of which a phase thereof is 90 degrees ahead of the second output signal Q2, the third shift register SR3 may output a third output signal Q3 and a third phase delay signal I3 of which a phase thereof is 90 degrees ahead of the third output signal Q3, and the fourth shift register SR4 may output a fourth output signal Q4 and a fourth phase delay signal I4 of which a phase thereof is 90 degrees ahead of the fourth output signal Q4.

Referring to FIG. 12, the first output signal Q1 and the second output signal Q2, the second output signal Q2 and the third output signal Q3, and the third output signal Q3 and the fourth output signal Q4 may respectively have a phase difference of 180 degrees. Each of the first phase delay signal I1 and the second phase delay signal I2, the second phase delay signal I2 and the third phase delay signal I3, and the third phase delay signal I3 and the fourth phase delay signal I4 may also have a phase difference of 180 degrees.

A random pattern generator according to an example embodiment of the present inventive concept may increase a pattern length and diversity of output data by logically combining output signals Q1 to Q4 and phase delay signals I1 to I4 having different phase differences of 90 degrees. As the pattern length of the output data increases, output power in a frequency domain may be distributed, which can improve electromagnetic interference generated in a power management unit receiving output data and operating.

Referring to FIGS. 10 and 13, in an example case in which the input data DIN is logic high and a clock signal CLK is a rising edge, the first shift register SR1 illustrated in FIG. 10 may output a first output signal Q1 which is logic high for one period of the clock signal CLK. The first shift register SR1 may output a first phase delay signal I1′ of which a phase thereof is 90 degrees delayed from the first output signal Q1.

Referring to FIG. 13, the second shift register SR2 illustrated in FIG. 10 may output a second output signal Q2 and a second phase delay signal I2′ of which a phase thereof is 90 degrees delayed from the second output signal Q2, the third shift register SR3 may output a third output signal Q3 and a third phase delay signal I3′ of which a phase thereof is 90 degrees delayed from the third output signal Q3, and the fourth shift register SR4 may output a fourth output signal Q4 and a fourth phase delay signal I4′ of which a phase thereof is 90 degrees delayed from the fourth output signal Q4.

A random pattern generator according to an example embodiment of the present inventive concept may increase a pattern length and diversity of output data by logically combining output signals Q1 to Q4 and phase delay signals I1′ to I4′ having different phase differences of 90 degrees. As the pattern length of the output data increases, output power in a frequency domain may be distributed, which can improve electromagnetic interference generated in a power management unit receiving output data and operating.

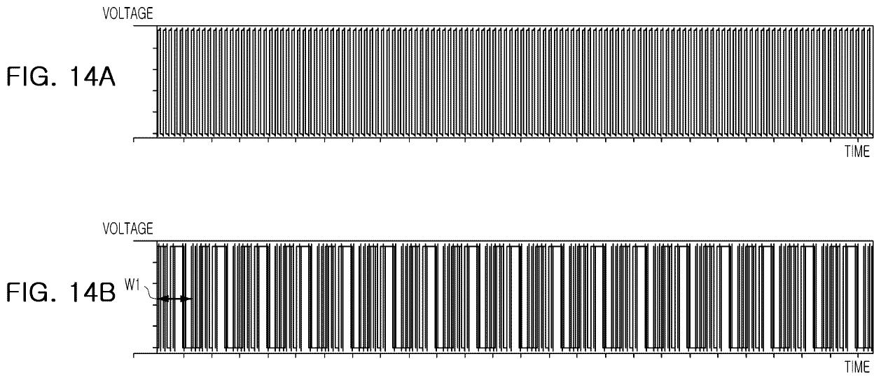

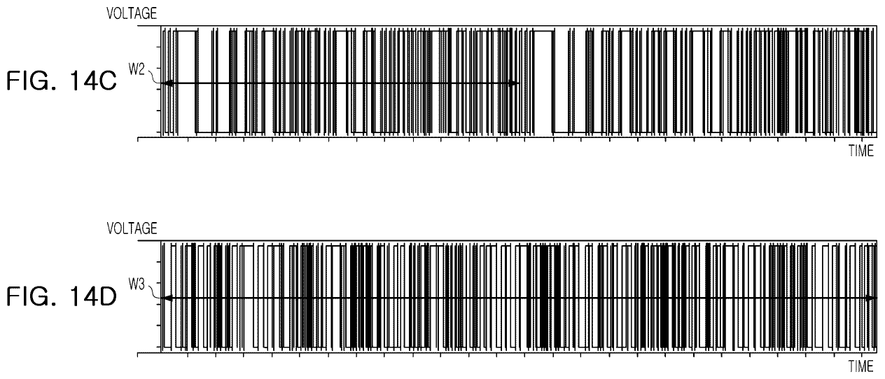

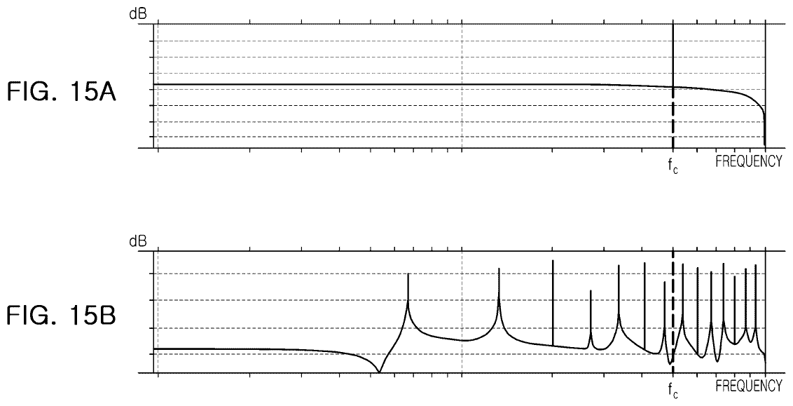

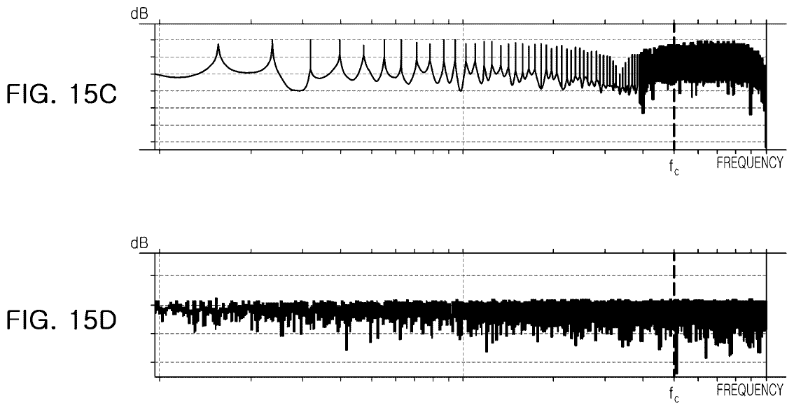

FIGS. 14A to 14D and 15A to 15D are diagrams provided to describe an operation of an image sensor according to an example embodiment of the present inventive concept.

FIGS. 14A to 14D are diagrams illustrating time-voltage characteristics of output data output from a random pattern generator according to an example embodiment of the present inventive concept. The random pattern generator according to an example embodiment of the present inventive concept may apply a PRBS pattern to output data using a plurality of shift registers, and may prevent energy from being concentrated on a specific frequency component and disperse power.

In an example case in which the number of shift registers included in the random pattern generator is N, the pattern length of the generated output data is defined as 2^{N-1}, and the pattern length of the output data may increase exponentially as N increases. In an example embodiment of the present inventive concept, the pattern length may mean the number of pulses included in the output data of N bits. For example, in an example case in which N is 4, the pattern length of the output data is 8, and in an example case in which N is 14, the pattern length of the output data may be extended to 8,192.

The output data of the PRBS pattern may be observed as a binary level signal which is irregularly distributed in a time domain, and may be observed as a power spectrum which is evenly distributed over a wide band in a frequency domain. As the pattern length of the output data increases, the concentration of single frequency components may be suppressed and the flatness of the spectrum can be improved. This can reduce electromagnetic interference generated in a power management unit and improve the performance of an image sensor.

FIGS. 14A to 14D are diagrams illustrating spectral characteristics of the PRBS pattern according to an increase in the number of shift registers according to an example embodiment of the present inventive concept. FIG. 14A may be a clock signal input to a random pattern generator. FIG. 14B illustrates output data in an example case in which the number of shift registers is 4, and unlike FIG. 14A, a PRBS pattern may be formed and the output data may have a first pattern length W1. FIG. 14C illustrates a case in which the number of shift registers is 7, in which case, a PRBS pattern may be formed and the output data may have a second pattern length W2. FIG. 14D illustrates a case in which the number of shift registers is 14, in which case, a PRBS pattern may be formed and the output data may have a second pattern length W3. It can be seen that each of a second pattern length W2 and a third pattern length W3 is increased compared to the first pattern length W1. As the number of shift registers increases and the pattern length of the output data also increases, a power spectrum may be uniformly distributed over a wide frequency band.

The random pattern generator according to an example embodiment of the present inventive concept may further increase the pattern length of output data by combining output signals output from each of a plurality of shift registers and phase delay signals having a phase difference of 90 degrees from the output signals. As the pattern length of the output data increases, the output data may distribute power thereof over a relatively wide frequency range rather than being concentrated in a specific frequency band. In an example case in which combining output signals of different phases and phase delay signals, the pattern length of the output data generated by the random pattern generator may be expanded to N×(2^{N-1}).

A random pattern generator according to an example embodiment of the present inventive concept may input output data having a PRBS pattern to a power management unit. The random pattern generator may increase the pattern length of the output data by combining an output signal and a phase delay signal, thereby preventing the energy of the output data from being concentrated on a specific frequency component, and distributing the power over a relatively wide frequency range. The random pattern generator may increase the pattern length of the output data by combining an output signal and a phase delay signal, thereby preventing the energy of the output data from being concentrated on a specific frequency component, and distributing the power over a relatively wide frequency range.

FIGS. 15A to 15D are graphs illustrating a frequency spectrum distribution measured according to a change in a length of a PRBS pattern according to an example embodiment of the present inventive concept, and graphs comparing an electromagnetic interference suppression effect according to a pattern length.

FIG. 15A illustrates frequency components for a clock signal input to a random pattern generator, and may have a power peak of approximately −3 dB at a center frequency f_{c}. FIG. 15B illustrates a case in which the number of shift registers is 4, and as a PRBS pattern is applied, a frequency component thereof is expanded compared to FIG. 15A, and a portion of power concentrated on the center frequency f_{c} component is dispersed, so that a peak may be reduced to about −12 dB.

FIG. 15C illustrates a case in which the number of shift registers is 7, and as a pattern length of the output data increases, frequency components included in the output data are expanded, and as a frequency band spreads widely, a peak power may be reduced to about −20 dB. FIG. 15D illustrates a case in which the number of shift registers is 14, and as a pattern length thereof increases, a power spectrum may be distributed flatly across the entire frequency band, and a peak at a center frequency f_{c} may be reduced to −30 dB or less.

Referring to FIGS. 14A to 14D, it can be seen that as the number of shift registers increases, the pattern length of the output data increases, and referring to FIGS. 15A to 15D, it can be seen that as the number of shift registers increases, the frequency component increases and the peak power decreases.

In an example embodiment of the present inventive concept, as the number of shift registers increases, the PRBS pattern length also increases, so that frequency components included in the same time period may increase, and energy concentrated at a specific frequency may be effectively distributed. A method of increasing the PRBS pattern length may effectively suppress electromagnetic interference to improve the performance of power management units based on high-speed switching or image sensors.

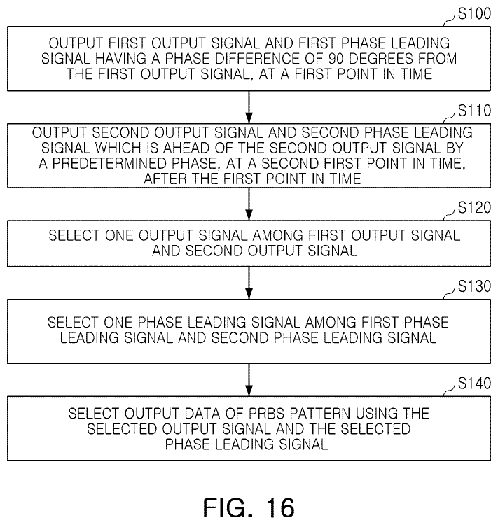

FIG. 16 is a flowchart provided to illustrate an operation of an image sensor according to an example embodiment of the present inventive concept.

For example, FIG. 16 illustrates a method for generating output data of a PRBS pattern by selectively combining an output signal and a phase delay signal according to an example embodiment of the present inventive concept. For example, a random pattern generator may receive an output clock signal from a phase-locked circuit, generate output data of a PRBS pattern based on the output clock signal, and input the output data to a power management unit. The random pattern generator may include a plurality of shift registers, XOR gates, and the like, and may generate output data by selectively combining an output signal and a phase delay signal.

According to an embodiment, in operation S100, the method may include outputting a first output signal and a first phase delay signal having a phase difference from the first output signal. For example, a first shift register included in the random pattern generator may output a first output signal and a first phase delay signal having a phase difference of 90 degrees from the first output signal, at a first point in time. In an example embodiment, the first phase delay signal may be a signal of which a phase thereof is 90 degrees ahead of the first output signal, or a signal of which a phase thereof is 90 degrees delayed from the first output signal. The first point in time may be a first rising edge of the clock signal while input data is being input.

According to an embodiment, in operation S110, the method may include outputting a second output signal and a second phase delay signal having a phase difference from the second output signal. For example, a second shift register included in the random pattern generator may output a second output signal and a second phase delay signal having a phase difference of 90 degrees from the second output signal, at a second point in time, after the first point in time. In an example embodiment, the second phase delay signal may be a signal of which a phase thereof is 90 degrees ahead of the second output signal, or a signal of which a phase thereof is 90 degrees delayed from the second output signal. The second point in time may be a second rising edge of the clock signal input to the random pattern generator.

According to an embodiment, a third shift register included in the random pattern generator may output a third output signal and a third phase delay signal having a phase difference of 90 degrees from the third output signal, at a third point in time, after the second point in time. According to an embodiment, fourth shift register included in the random pattern generator may output a fourth output signal and a fourth phase delay signal having a phase difference of 90 degrees from the fourth output signal, at a fourth point in time, after the third point in time. The third point in time may be a third rising edge of the clock signal, and the fourth point in time may be a fourth rising edge of the clock signal. The number of output signals and phase delay signals may be determined by the number of shift registers included in the random pattern generator.

According to an embodiment, in operation S120, the method may include selecting an output signal among a first output signal and a second output signal. For example, the random pattern generator may select one output signal among a first output signal and a second output signal. The random pattern generator may include a first multiplexer, and the first multiplexer receive the first output signal and the second output signal, and select and output one output signal among the first output signal and the second output signal by the first selection signal. In another example embodiment, the first multiplexer may select and output one of the first to fourth output signals. However, an example embodiment thereof is not limited thereto, and the number of signals input to the first multiplexer may be determined according to the number of shift registers.

According to an embodiment, in operation S130, the method may include selecting a phase delay signal among a first phase delay signal and a second phase delay signal. For example, the random pattern generator may select one phase delay signal among a first phase delay signal and a second phase delay signal. For example, the second multiplexer may receive the first phase delay signal and the second phase delay signal, and select and output one phase delay signal among the first phase delay signal and the second phase delay signal by the second selection signal. In another example embodiment, the second multiplexer may select and output one of the first to fourth phase delay signals. However, an example embodiment thereof is not limited thereto, and the number of signals input to the second multiplexer may be determined according to the number of shift registers.

According to an embodiment, in operation S140, the method may include generating output data of a PRBS pattern by using the selected output signal and the selected phase delay signal. For example, the random pattern generator may generate output data of a PRBS pattern by using the selected output signal and the selected phase delay signal. The random pattern generator may generate output data by performing an XOR operation on the output signal output from the first multiplexer and the phase delay signal output from the second multiplexer. By combining the output signal and the phase delay signal to increase a pattern length of the output data, energy of the output data may be prevented from being concentrated on a specific frequency component and power may be distributed over a relatively wide frequency range. Therefore, electromagnetic interference generated in the power management unit may be effectively suppressed and the performance of the image sensor may be improved.

According to an example embodiment of the present inventive concept, a phase-locked loop may generate an output clock signal, and a random pattern generator may generate output data of a PRBS pattern based on the output clock signal and supply the output data to a power management unit.

The random pattern generator may supply output data having a relatively spread frequency band to a power management unit, thereby reducing power consumed by an image sensor and an area of the image sensor, and improving electromagnetic interference generated in the power management unit, thereby improving the performance of the image sensor.

The various and advantageous advantages and effects of the present inventive concept are not limited to the above description, and may be more easily understood in the course of describing the specific embodiments of the present inventive concept. While example embodiments have been shown and described above, it will be apparent to those skilled in the art that modifications and variations could be made without departing from the scope of the present inventive concept, as defined by the appended claims.

While example embodiments have been shown and described above, it will be apparent to those skilled in the art that modifications and variations could be made without departing from the scope of the present inventive concept as defined by the appended claims.

What is claimed is:

1. An image sensor, comprising:
a phase-locked loop (PLL) circuit configured to generate an output clock signal, and receive a feedback signal corresponding to the output clock signal;
a random pattern generator circuit configured to receive the output clock signal and generate output data of a Pseudo Random Binary Sequence (PRBS) pattern; and
a power management unit (PMU) circuit configured to receive the output data and operate based on the output data.

2. The image sensor of claim 1, wherein the PLL circuit comprises the random pattern generator circuit.

3. The image sensor of claim 1, wherein the PMU circuit comprises the random pattern generator circuit.

4. The image sensor of claim 1, wherein the random pattern generator circuit is connected between the PLL circuit and the PMU circuit.

5. The image sensor of claim 1, wherein the PLL circuit is configured to operate in a Mobile Industry Processor Interface (MIPI) high-speed serial interface.

6. The image sensor of claim 1, wherein the random pattern generator circuit comprises a plurality of shift registers connected to each other in series,
wherein, each of the plurality of shift registers is configured to output an output signal and a phase modified signal having a phase difference of 90 degrees from the output signal.

7. The image sensor of claim 6, wherein the phase modified signal is a signal having a phase, which is 90 degrees delayed from the output signal.

8. The image sensor of claim 6, wherein the phase modified signal is a signal having a phase, which is 90 degrees ahead of the output signal.

9. The image sensor of claim 6, wherein a pattern length of the output data is the same as a number of the plurality of shift registers.

10. The image sensor of claim 6, wherein the random pattern generator circuit is further configured to generate the output data by combining one of a plurality of output signals and one of a plurality of phase modified signals.

11. The image sensor of claim 6, wherein each of the plurality of shift registers is configured to operate based on the output clock signal.

12. The image sensor of claim 6, wherein the plurality of shift registers is 2 or more shift registers.

13. An operating method of a random pattern generator circuit, comprising:
receiving an output clock signal in a phase-locked loop (PLL) circuit;
outputting a first output signal and a first phase modified signal having a phase difference of 90 degrees from the first output signal, at a first point in time;
outputting a second output signal and a second phase modified signal having a phase difference of 90 degrees from the second output signal, at a second point in time after the first point in time based on the output clock signal;
selecting one output signal among the first output signal and the second output signal;
selecting one phase modified signal among the first phase modified signal and the second phase modified signal;
generating output data of a Pseudo Random Binary Sequence (PRBS) pattern based on the selected output signal and the selected phase modified signal; and
supplying the output data to a power management unit (PMU) circuit.

14. The operating method of a random pattern generator circuit of claim 13, further comprising:
outputting a third output signal and a third phase modified signal having a phase difference of 90 degrees from the third output signal, at a third point in time after the second point in time based on the output clock signal;
outputting a fourth output signal and a fourth phase modified signal having a phase difference of 90 degrees from the fourth output signal, at a fourth point in time after the third point in time based on the output clock signal;
selecting the output signal from among the first output signal, the second output signal, the third output signal, and the fourth output signal;
selecting the phase modified signal from among the first phase modified signal, the second phase modified signal, the third phase modified signal, and the fourth phase modified signal; and
generating the output data of the PRBS pattern based on the selected output signal and the selected phase modified signal.

15. The operating method of a random pattern generator circuit of claim 13, further comprising:
receiving, by a first multiplexer included in the random pattern generator circuit, the first output signal and the second output signal, selecting one of the first output signal and the second output signal by a first selection signal and outputting the selected one of the first output signal and the second output signal;
receiving, by a second multiplexer included in the random pattern generator circuit, the first phase modified signal and the second phase modified signal, selecting one of the first phase modified signal and the second phase modified signal by a second selection signal and outputting the selected one of the first phase modified signal and the second phase modified signal; and
generating the output data by performing an XOR operation on the output signal output from the first multiplexer and the phase modified signal output from the second multiplexer.

16. The operating method of a random pattern generator circuit of claim 13, wherein the first point in time and the second point in time are respectively rising edges of the output clock signal.

17. A phase-locked loop (PLL) circuit, comprising:
a voltage controlled oscillator circuit configured to generate an output clock signal;
a divider circuit configured to receive the output clock signal, and divide the output clock signal into a feedback clock signal having a constant phase difference;
a phase frequency detector circuit configured to a difference in phase and frequency between a reference clock signal and the feedback clock signal, and adjust a control voltage input to the voltage controlled oscillator circuit to reduce the difference; and
a random pattern generator circuit configured to receive the output clock signal, generate output data of a Pseudo Random Binary Sequence (PRBS) pattern, and input the output data to a power management unit (PMU) circuit.

18. The phase-locked loop of claim 17, further comprising:
a pre-divider circuit configured to device an external clock by a predetermined multiple and generate the reference clock signal.

19. The phase-locked loop of claim 17, further comprising:
a post-divider circuit configured to divide the output signal into a predetermined multiple and input the same to the random pattern generator circuit.

20. The phase-locked loop of claim 17, wherein,
based on the feedback clock signal being slower than the reference clock signal, a level of the control voltage increases, and
based on the feedback clock signal being faster than the reference clock signal, the level of the control voltage decreases.
